(19) United States
(12) Patent Application Publication
(10) Pub. No.: US 2025/0194267 A1
(43) Pub. Date: Jun. 12, 2025

(54) IMAGE SENSOR MANUFACTURING METHOD

(71) Applicants: STMicroelectronics International N.V., Geneva (CH); COMMISSARIAT A L'ENERGIE ATOMIQUE ET AUX ENERGIES ALTERNATIVES, Paris (FR)

(72) Inventors: Pierre BAR, Grenoble (FR); Marc GUILLERMET, Grenoble (FR)

(73) Assignees: STMicroelectronics International N.V., Geneva (CH); COMMISSARIAT A L'ENERGIE ATOMIQUE ET AUX ENERGIES ALTERNATIVES, Paris (FR)

(21) Appl. No.: 18/962,812

(22) Filed: Nov. 27, 2024

(30) Foreign Application Priority Data
Dec. 11, 2023 (FR) 2313932

(51) Int. Cl. H10F 39/00; H10K 39/32

(52) U.S. Cl. CPC H10F 39/024; H10F 39/8063; H10F 39/811; H10K 39/32

(57) ABSTRACT

A method of manufacturing an image sensor comprising the forming of an opening in a substrate, the forming of a conductive pad covering the flanks of the opening and delimiting a gap in the opening, the forming of microlenses in a layer made of a first resin, the layer made of the first resin covering the pad and penetrating into the gap, the forming of a mask made of a second resin on top of and in contact with the layer made of the first resin, the chemical plasma etching of the layer made of the first resin, through the mask, delimiting a block of the first resin in the gap, the deposition of a protective layer on the microlenses and on the block, the removal of the portion of the protective layer covering the block, and the etching of the block.

### CROSS-REFERENCE TO RELATED APPLICATION(S)

This application claims the priority benefit of French patent application number 23/13932, filed on Nov. 12, 2023, entitled “Procédé de fabrication d'un capteur d′images”, which is hereby incorporated by reference to the maximum extent allowable by law.

### BACKGROUND

### Technical Field

The present description generally concerns the field of image sensors and more particularly aims at an image sensor manufacturing method.

### Description of the Related Art

An image sensor generally comprises a plurality of photodetectors, for example, photodiodes, integrated inside and on top of a semiconductor substrate.

Image sensors having their photodetectors topped with a layer of microlenses are more particularly considered herein. This microlens layer enables to focus the incident radiation onto the photodetectors.

It would be desirable to improve at least certain aspects of known methods of manufacturing an image sensor comprising a microlens layer.

### BRIEF SUMMARY

An embodiment overcomes all or part of the disadvantages of known image sensors.

An embodiment provides a method of manufacturing an image sensor comprising the following steps, in the order:
a) the forming of an opening in a semiconductor substrate comprising a first surface and a second surface opposite to the first surface, the opening extending from the first surface to the second surface, and the forming of at least one electrically-conductive pad comprising a first portion extending over the first surface and a second portion covering the sides of the opening and delimiting a gap in the opening;
b) the forming of a plurality of microlenses in a layer made of a first resin, the layer made of the first resin covering the electrically-conductive pad and penetrating into the gap;
c) the forming of a mask made of a second resin on top of and in contact with the layer made of the first resin;
d) the chemical plasma etching of the layer made of the first resin, through the mask delimiting a block of the first resin in the gap;
e) the deposition of a protective layer on the plurality of microlenses and on the block;
f) the removal of the protective layer covering the block; and
g) the etching of the block.

According to an embodiment, the method comprises, at step a), the forming of a plurality of photodetectors in the semiconductor substrate.

According to an embodiment, during step d), the contact pad is exposed.

According to an embodiment, at step b), the forming of the microlenses comprises a step h) of forming of structures in the form of microlenses in a layer made of a third resin, followed by a step i) of transfer of said structures into the layer made of the first resin by physical etching.

According to an embodiment, at step h), the structures are formed by photolithography and flow.

According to an embodiment, after step d), the mask is removed by means of a solvent.

According to an embodiment, the layer made of the first resin is crosslinked.

According to an embodiment, the layer made of the first resin is non-photosensitive.

According to an embodiment, the plasma used during steps d) and g) comprises oxygen.

According to an embodiment, the protective layer is made of an oxide, for example of silicon oxynitride (SiON).

An embodiment also provides an image sensor comprising:
a semiconductor substrate inside and on top of which are integrated a plurality of photodetectors, the semiconductor substrate comprising a first surface and a second surface opposite to the first face and an opening extending from the first surface to the second surface;
an electrically-conductive pad comprising a first portion extending over the first surface and a second portion covering the flanks of the opening and delimiting a gap in the opening;
a layer made of a first resin covering the first surface in which are formed a plurality of microlenses, said layer made of the first resin comprising an opening facing the electrically-conductive pad, said opening having inclined side walls; and
a protective layer covering the layer made of the first resin and which does not extend inside or on top of the gap.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the drawings, in which:

FIG. 1, FIG. 2, FIG. 3, FIG. 4, FIG. 5, FIG. 6, FIG. 7, FIG. 8, FIG. 9, and FIG. 10 are cross-section views illustrating a device obtained at the end of successive steps of an example of an image sensor manufacturing method;

FIG. 11 and FIG. 12 are drawings respectively similar to FIGS. 6 and 7 illustrating disadvantages of the method illustrated in FIGS. 1 to 10;

FIG. 13, FIG. 14, FIG. 15, FIG. 16, FIG. 17, and FIG. 18 are images obtained by scanning electron microscopy illustrating disadvantages of the method illustrated in FIGS. 1 to 10;

FIG. 19, FIG. 20, FIG. 21, FIG. 22, FIG. 23, FIG. 24, and FIG. 25 are cross-section views illustrating a device obtained at the end of successive steps of an image sensor manufacturing method according to an embodiment;

FIG. 26, FIG. 27, and FIG. 28 are cross-section views illustrating a device obtained at the end of successive steps of an image sensor manufacturing method according to another embodiment; and

FIG. 29 and FIG. 30 are images obtained by scanning electron microscopy obtained during the implementation of the method illustrated in FIGS. 19 to 25.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the forming of the photodetectors of the described image sensors, as well as of their control circuits, have not been detailed, the forming of these elements being within the abilities of those skilled in the art based on the indications of the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%. Further, the terms “insulating” and “conductive” here respectively signify “electrically insulating” and “electrically conductive”.

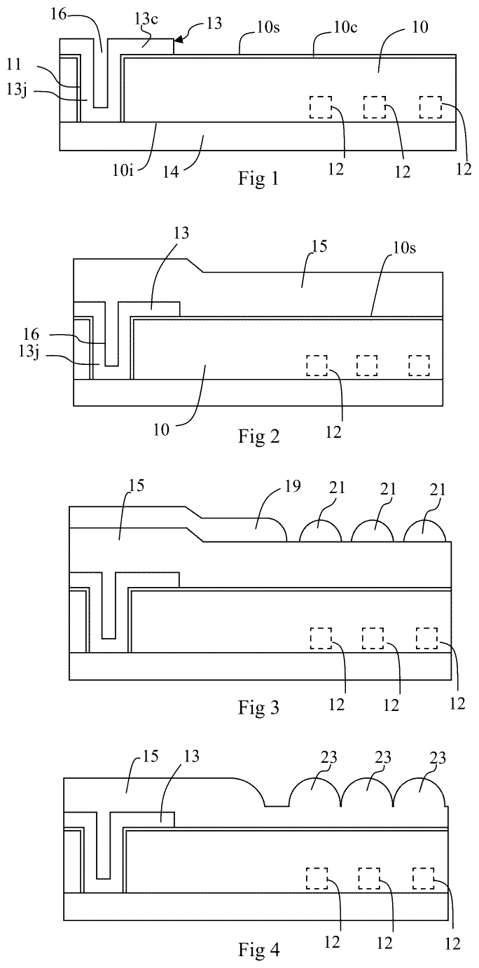

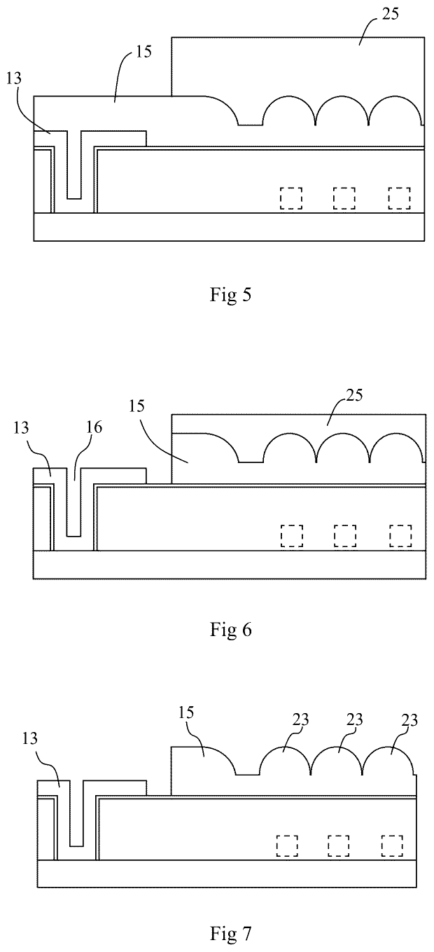

FIGS. 1 to 10 illustrate, schematically and partially, devices or structures obtained at the end of successive steps of an example of an image sensor manufacturing method.

More particularly, FIG. 1 corresponds to an initial structure comprising a semiconductor substrate 10, for example a silicon substrate, in which photodetectors 12 have been previously formed. As an example, photodetectors 12 are photodiodes, for example, adapted to capturing an infrared, visible, and/or ultraviolet radiation. As an example, photodetectors 12 are photodetectors made in CMOS (Complementary Metal Oxide Semiconductor) technology.

Substrate 10 comprises an upper surface 10s and a lower surface 10i, opposite to upper surface 10s. According to an embodiment, upper surface 10s is planar. Substrate 10 comprises a dielectric layer 10c which delimits upper surface 10s. Substrate 10 may be covered, on the side of upper surface 10s, by one or more than one elements, not shown in the drawings, for example colored filters covering photodetectors 12, an opaque screen covering areas of substrate 10 comprising no photodetectors 12, etc. Substrate 10 is covered, on the side of lower surface 10i, with an interconnection structure 14, comprising a stack of insulating layers having conductive tracks, not shown, extending therebetween and having conductive vias, not shown, extending therethrough. According to an embodiment, substrate 10 has a thickness in the range from 3 μm to 10 μm.

In this example, substrate 10 is intended to be illuminated from its upper surface 10s. The initial structure further comprises one or a plurality of contact pads 13, a single contact pad 13 being shown in FIG. 1. According to an embodiment, contact pad 13 is electrically insulated from the substrate by at least one insulating layer, not shown. Pads 13 are arranged out of line with photodetectors 12 so as not to mask photodetectors 12. As an example, in top view, the photodetectors 12 of the image sensor are located in a central region of substrate 10, and pads 13 are located in front of a peripheral region of substrate 10. The pads 13 are spaced along a horizontal direction from the photodetectors 12.

Each contact pad 13 comprises a contact area 13c which extends over the upper surface 10s of substrate 10. The contact area 13c of each pad 13 is intended to be connected to an external device, for example by means of an electrically-conductive wire, for example a metal wire. Substrate 10 comprises, for each contact pad 13, a through opening 11 which extends from upper surface 10s to lower surface 10i. Dielectric layer 10c may further cover the side walls of opening 11. According to an embodiment, opening 11 has a substantially constant cross-section, seen in a direction perpendicular to surface 10s. As an example, the cross-section of opening 11 is square or rectangular, in particular inscribed within a rectangle having its short side length varying from 2 μm to 10 μm and having its long side length varying from 3 μm to 10 μm. Contact pad 13 comprises a junction portion 13j which extends in through opening 11. As an example, the junction portion 13j of contact pad 13 is connected to one or a plurality of metallization levels of the interconnection structure 14 arranged on the side of the lower surface 10i of substrate 10. As an example, contact pads 13 are made of a metallic material, for example of aluminum. Junction portion 13j covers the flanks of opening 11. However, opening 11 may not be completely filled by junction portion 13j, so that an air-filled gap 16, emerging onto the outside, may remain in opening 11. As an example, junction portion 13j has a thickness, measured with respect to the flanks of opening 11, which is in the range from 0.3 μm to 2 μm, and is for example equal to approximately 1 μm. As an example, the depth of gap 16 is in the range from 1 μm to 10 μm, and is for example equal to approximately 6 μm. As an example, contact pads 13 may be used for the exchange of signals with the image sensor and/or for the power supply of the image sensor. According to another example, one of contact pads 13 may form part of a protective structure such as a seal ring of interconnection structure 14, in which case the pad may extend along the entire periphery of the image sensor.

FIGS. 2 to 4 illustrate devices obtained at the end of steps of forming of a layer of microlenses on the side of the upper surface 10s of substrate 10, facing photodetectors 12.

FIG. 2 illustrates a device obtained at the end of a step of forming a resin layer 15 on the side of the upper surface 10s of substrate 10.

Layer 15 is deposited, for example, all over the upper surface 10s of substrate 10. Layer 15 thus covers contact pads 13 and photodetectors 12. Layer 15 penetrates in particular into the gap 16 delimited by the junction portion 13j of each contact pad 13. Layer 15 is made of a resin transparent to the detection wavelengths of the sensor. Layer 15 has a thickness in the range from 1 μm to 6 μm, for example, in the order of 4 μm.

The resin of layer 15 is, for example, a crosslinked resin which cannot be dissolved in usual liquid solvents for developing and/or etching resins. The resin of layer 15 is, for example, a non-photosensitive resin. As an example, the resin of layer 15 is selected so that it can be crosslinked, for example by UV or from a certain temperature, for example, in the order of 200° C. As an example, the resin of layer 15 is selected so that it can be etched by means of an oxygen-based non-remote reactive ion plasma or RIE (Reactive Ion Etching). As an example, the resin of layer 15 comprises a polymer, for example of non-developable acrylic type.

FIG. 3 illustrates a device obtained at the end of a step of forming an etch mask 19 on the upper surface of resin layer 15. Mask 19 comprises structures in the form of microlenses, intended to be transferred into resin layer 15 during a subsequent etching step, to form microlenses in layer 15.

As an example, mask 19 is formed from a resist layer. The resist of mask 19 is first deposited all over the upper surface of layer 15, on top of and in contact therewith. At this stage, the resist of mask 19 for example has a substantially uniform thickness over the entire surface of the structure. The deposition of the resist of mask 19 may be performed by a spin-coating technique or by any other adapted deposition technique. The resist layer of mask 19 is then structured, for example by photolithography, so as to form, opposite photodetectors 12, separate resist pads 21. In this example, an individual resist pad 21 is provided opposite each photodetector 12 of the sensor. A flow anneal is then implemented, during which resist pads 21 deform to take the shape of microlenses. After the flow, resin pads 21 are for example separated. The described embodiments are however not limited to this specific case. Pads 21 for example have a thickness smaller than the thickness of layer 15.

FIG. 4 illustrates a device obtained at the end of a step of reactive ion etching of layer 15 and of mask 19, resulting in transferring the pattern of mask 19 into an upper portion of layer 15. The etching is for example stopped when all the resin of mask 19 has been consumed.

Thus, in the device illustrated in FIG. 4, layer 15 comprises microlenses 23 facing photodetectors 12. As an example, microlenses 23 have a height in the range from 0.5 μm to 4 μm. At this stage, connection pads 13 remain covered by the resin of layer 15.

FIGS. 5 to 7 illustrate devices obtained at the end of steps of removal of the resin of layer 15 opposite and on pads 13, to enable to achieve an electric contact on pads 13.

FIG. 5 illustrates a device obtained at the end of a step of forming a resin masking layer 25 on the upper surface of layer 15.

As an example, layer 25 is first deposited all over the upper surface of layer 15, for example in contact with the upper surface of layer 15. Layer 25 is then removed, for example by photolithography, opposite and over pads 13, so as to expose the portion of resin layer 15 coating pads 13. The resin of layer 25 is, for example, a resist. As an example, layer 25 has a thickness greater than the maximum thickness of layer 15. As an example, layer 25 has a thickness in the range from 4 μm to 10 μm, for example in the order of 6 μm.

FIG. 6 illustrates a device obtained at the end of a step of reactive ion etching (RIE) of layer 15 through layer 25. During this step, layer 25 is used as an etch mask.

More particularly, during this step, the portion of layer 15 not covered by layer 25 is removed to expose the upper surface of contact pads 13.

The etching used in this step is a reactive ion etching. Such an etching causes a removal of material by bombardment, for example, by using an oxygen-based plasma. The plasma used during this etch step has, for example, a different chemical composition than the plasma used in the etching resulting in the forming of microlenses 23. During the above-mentioned step, layers 25 and 15 are consumed simultaneously. The etch step is stopped, for example, when contact pads 13 are fully exposed and there remains no further residues of layer 15 on their surface or in gaps 16. At this stage, a portion of layer 25 remains on the surface of layer 15 opposite microlenses 23. In some embodiments, a portion of the dielectric layer 10c or the surface 10s of the substrate is exposed, the exposed portion being between the pad 13 and the layer 15. A side surface of the layer 15 is opposite and faces a side surface of the pad 13, the side surfaces being spaced by the exposed portion of the dielectric layer 10c or substrate 10.

FIG. 7 illustrates a device obtained by removal of the remaining portion of layer 25 so as to expose the upper surface of microlenses 23. This removal step is for example carried out by wet solvent etching, by means of an etching solution enabling to remove the material of layer 25 selectively over the material of layer 15.

FIG. 8 illustrates a device obtained at the end of a step of deposition of a protective layer 29 made of an electrically-insulating material at the surface of the device illustrated in FIG. 7.

Layer 29 for example extends continuously over the entire upper surface of the device of FIG. 7. Thus, layer 29 particularly covers the microlenses 23 of layer 15 and pads 13. As an example, layer 29 is made of a material which enables to protect layer 15 from humidity. Layer 29 is for example made of an oxide, for example of silicon oxynitride (SiON). In some embodiments, layer 29 contacts and is on the exposed portion of the dielectric layer 10c or substrate 10 and the side surfaces of the pad 13 and layer 15.

As an example, protective layer 29 is deposited, by a method of conformal deposition on the upper surface of the device shown in FIG. 7, for example by chemical vapor deposition, for example a plasma-enhanced chemical vapor deposition (PECVD). Layer 29 for example has a thickness in the range from 50 nm to 500 nm, for example in the order of 200 nm.

FIGS. 9 and 10 illustrate devices obtained at the end of steps of local removal of protective layer 29 opposite and on the contact area 13c of each of contact pads 13, to allow the achieving of an electric contact on pads 13.

FIG. 9 illustrates a device obtained at the end of a step of deposition of a resin layer 31 on the upper surface of the device of FIG. 8, and of forming, in resin layer 31, of a through opening 32 emerging to protective layer 29 opposite the contact area 13c of pad 13. Opening 32 is for example formed by photolithography.

FIG. 10 illustrates a device obtained at the end of a step of etching of protective layer 29 at the bottom of opening 32, by using resin layer 31 as an etch mask. At the end of this etching, layer 31 is removed, in particular from the bottom of gap 16.

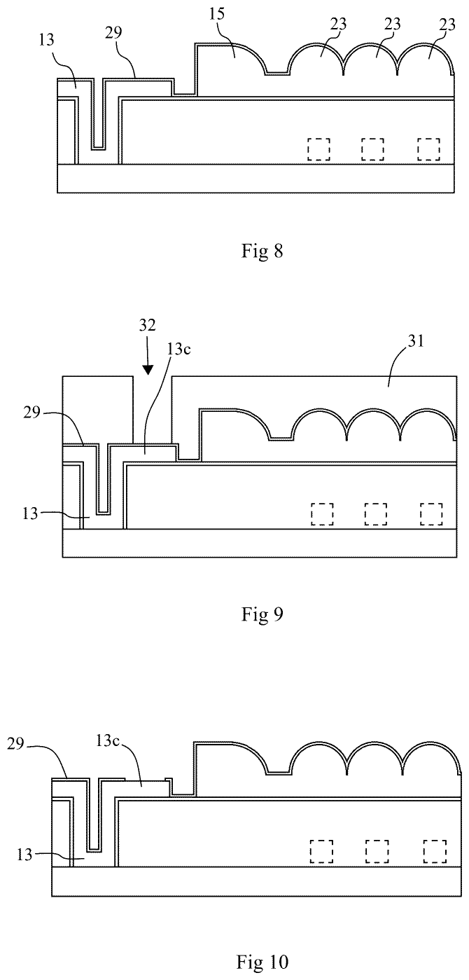

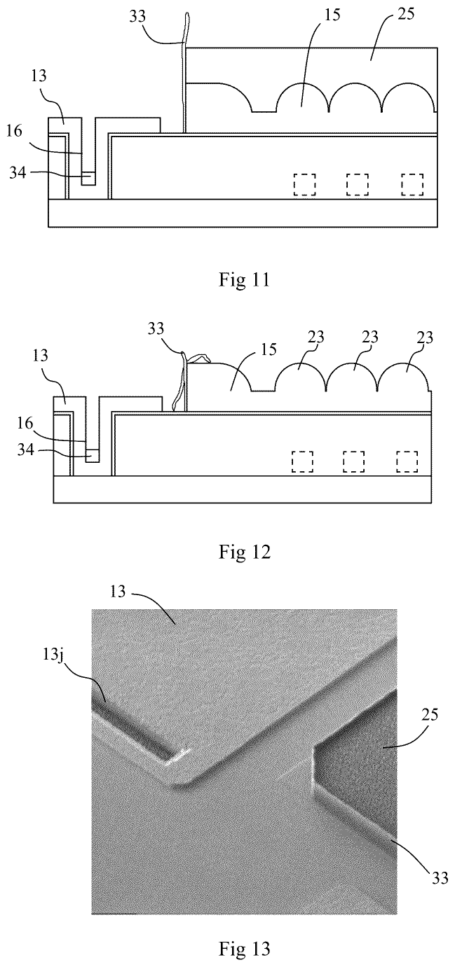

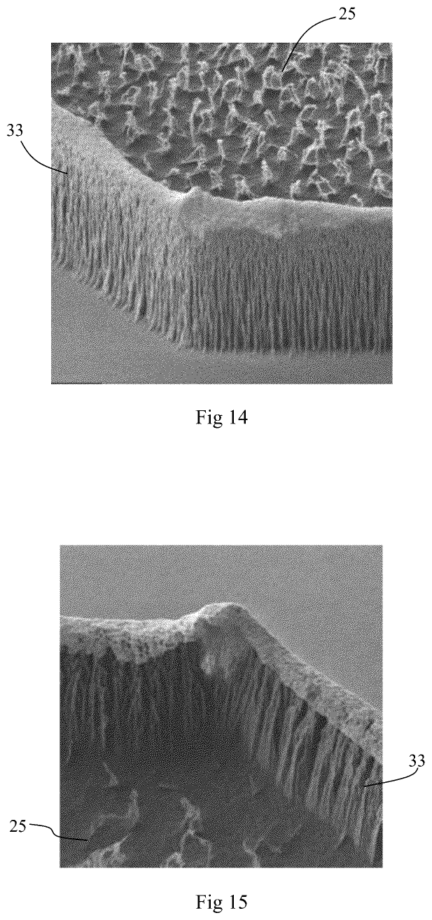

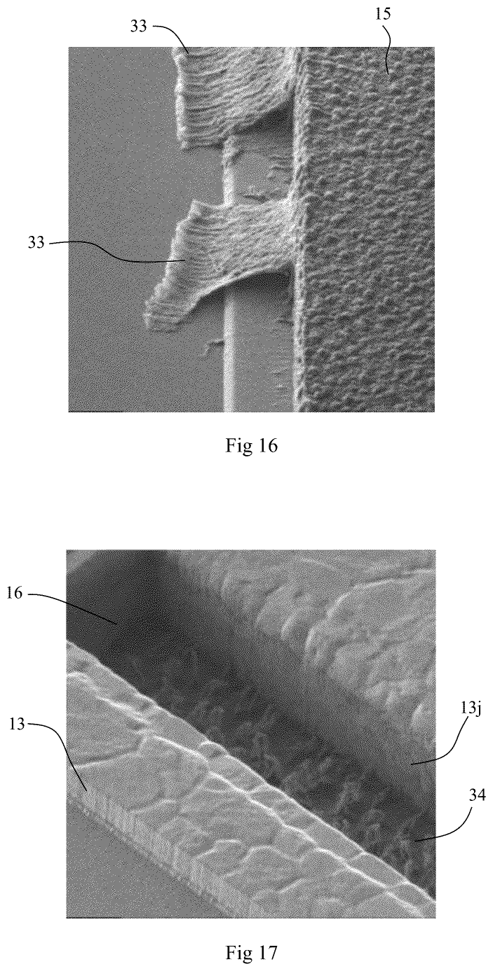

FIGS. 11 and 12 are drawings respectively similar to FIGS. 6 and 7, and illustrate disadvantages of the method described hereabove in relation with FIGS. 1 to 10. FIG. 13, FIG. 14, and FIG. 15 are images obtained by scanning electron microscopy of a device at the step illustrated in FIG. 11. FIG. 16, FIG. 17, and FIG. 18 are images obtained by scanning electron microscopy of a device at the step illustrated in FIG. 12.

A disadvantage of the method described hereabove is that, at the step described in relation with FIG. 6, the etching by ion bombardment of layers 15 and 25 results in the forming of residual fibers or filaments 33 on the flanks of layer 15 and of layer 25, as schematically shown in FIG. 11 and as can be seen in FIGS. 13, 14, and 15. These residual fibers or filaments 33 are defects induced by the reactive ion etching and are made, for example, of carbon, of oxygen, and of silicon in the form of polymers. These residual fibers or filaments 33 may in particular extend beyond the flanks of layer 15, over the flanks of layer 25. The residual fibers or filaments 33 non-homogeneously cover the flank of layer 15. At least part of these residual fibers or filaments 33 may still be present after the step of removal of layer 25, as schematically shown in FIG. 12 and as can be seen in FIG. 16.

Thus, due to the presence of the residual fibers or filaments 33, the layer 29 deposited at the step described in relation with FIG. 8 in particular exhibits uneven thickness which may result in sealing and integrity defects which are problematic for the subsequent manufacturing steps and for the reliability of the device. A specific step of removal of the residual fibers or filaments 33 by wet etching may be provided between the step described in relation with FIG. 7 and the step described in relation with FIG. 8. This wet etching may, for example, be carried out with a solvent. However, this step generates an excess cost and does not allow a full removal of the residual fibers or filaments 33 without damaging the microlens layer 23.

Another disadvantage of the above-described method is that a block 34 of the material forming layer 15 may remain in the gap 16 delimited by each contact pad 13 at the end of the step of etching of layer 15, as schematically shown in FIGS. 11 and 12 and as can be seen in FIG. 17. Blocks 34 may be totally or partly detached, for example during the subsequent manufacturing steps as can be seen in FIG. 18, and may thus be problematical for the subsequent manufacturing steps and for the reliability of the device.

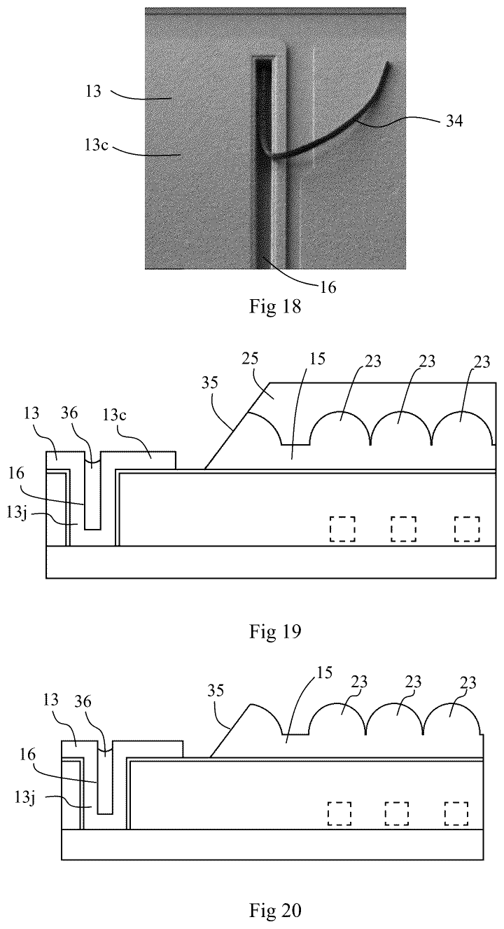

FIGS. 19 to 25 illustrate, schematically and partially, devices obtained at the end of successive steps of a method of manufacturing an image sensor according to an embodiment.

The initial steps of the method are, for example, identical or similar to those described hereabove in relation to FIGS. 1 to 5 and will not be detailed again hereafter.

According to an embodiment, it is provided to replace the step of reactive ion etching (anisotropic etching) of resin layer 15 described in relation with FIG. 6 with a so-called remote, and thus isotropic, plasma etching step. This remote plasma etching is based on the use of free radicals. Such an etching implements equipment different from that used for the step of physical etching described in relation with FIG. 6. This etching technique is usually used to remove, recycle, or fully strip resin layers. This technique is further sometimes used to carry out chemical treatments all over the exposed materials. It is here provided to use it, in uncommon fashion, to perform a local etching of resin layer 15 through the mask formed by resin layer 25. This technique has the advantage of being less aggressive than reactive ion etching (RIE), and does not generate polymer fibers or filaments on the flanks of layer 15 and on the top of a resin block present in gap 16. This removal technique also has the advantage of being highly selective over dielectric layer 10c.

FIG. 19 illustrates a device obtained at the end of the step of remote plasma etching of resin layer 15 through the mask formed by resin layer 25.

The remote plasma etching method implemented to obtain the device shown in FIG. 19 consumes layers 25 and 15 simultaneously and isotropically. Thus, at the end of the etch step, layers 15 and 25 have an inclined (non-vertical) or slanted flank 35. As an example, the inclination of the flank 35 of layers 25 and 15 may be controlled by a control of the etching time.

The plasma used for the remote plasma etching preferably comprises oxygen. As an example, the etching plasma mainly comprises oxygen and may contain nitrogen and hydrogen. As an example, the temperature of the material etched during this step is in the range from 130° C. to 250° C., for example in the order of 150° C.

The above-mentioned etching is stopped when contact pads 13 are exposed and there remains no residues of layer 15 on the surface of contact areas 13c. At this stage, a portion of layer 25 remains at the surface of layer 15 opposite microlenses 23. Further, a block 36 of the material forming layer 15 is present in the gap 16 delimited by portion 13j of contact pad 13.

FIG. 20 illustrates a device obtained at the end of a step of removal of the remaining portion of layer 25 to expose the upper surface of microlenses 23. This removal step is for example carried out by wet etching, by means of a solvent-type solution enabling to remove the material layer 25 selectively over the material of layer 15.

FIG. 21 illustrates a device obtained at the end of a step of deposition of a protective and insulating layer 40 made of an electrically-insulating material at the surface of the device illustrated in FIG. 20. In particular, protective layer 40 covers layer 15, and in particular microlenses 23, contact pads 13, and the blocks 36 present in the gaps 16 delimited by contact pads 13.

According to an embodiment, protective layer 40 is made of the same material as the previously-described layer 29. As an example, layer 40 is made of a material which enables to protect layer 15 from humidity, and from the various sawing and packaging processes. Layer 40 is for example made of an oxide, for example, of silicon oxynitride (SiON). As an example, protective layer 40 is deposited, by a method of conformal deposition on the upper surface of the device illustrated in FIG. 20, for example by chemical vapor deposition, for example a plasma-enhanced chemical vapor deposition (PECVD). Layer 40 has, for example, a thickness in the range from 50 nm to 500 nm, for example in the order of 200 nm.

FIG. 22 illustrates a device obtained at the end of a step of deposition of a resin layer 41 over the entire structure obtained in FIG. 21, in particular over the entire protective layer 40.

FIG. 23 illustrates a device obtained at the end of a step of forming of an opening 42 in resin layer 41 to expose protective layer 40 vertically in line with each contact pad 13.

FIG. 24 illustrates a device obtained at the end of a step of removal of protective layer 40 in each opening 42 opposite pads 13. In particular, the exposed portion of the protective layer 40 is removed to expose the block 36 contained in the gap 16 delimited by each pad 13. Surfaces of the pad are also exposed.

FIG. 25 illustrates a device obtained at the end of a step of removal of resin layer 41 and of the blocks 36 present in the gaps 16 delimited by the junction portions 13j of contact pads 13. The removal of block 36 may be achieved by the same etching method as that described hereabove in relation with FIG. 19. In some embodiments, the block 36 is etched via chemical plasma etching. Protective layer 40 can then act as an etch stop layer for the etching of resin layer 41. More particularly, during this step, the blocks 36 of the material of layer 15 are etched so as to expose the outer surface of contact pads 13 in gaps 16. Protective layer 40 protects microlenses 23 during the etching of resin layer 41 and of block 36.

According to an embodiment, resin layer 41 and blocks 36 are removed by a step of remote plasma etching, for example by means of a microwave stripper or of an ex-situ, and thus isotropic, resin removal. This etching is based on the use of free radicals generated by remote plasmas. The etching plasma used preferably comprises oxygen. As an example, the etching plasma mainly comprises oxygen, nitrogen, and hydrogen. As an example, the temperature of the material etched during this step is in the range from 130° C. to 250° C., for example in the order of 170° C. The etch step is for example stopped when contact pads 13 are fully exposed and there remain no residues of layer 15 in gaps 16. This method being highly selective over protective layer 40, it is then possible to perfectly remove the resin residues from blocks 36 and from resin layer 41, whatever the dimensions selected for openings 11 and gaps 16, without altering lenses 23 and layer 15 perfectly encapsulated by this protective layer 40.

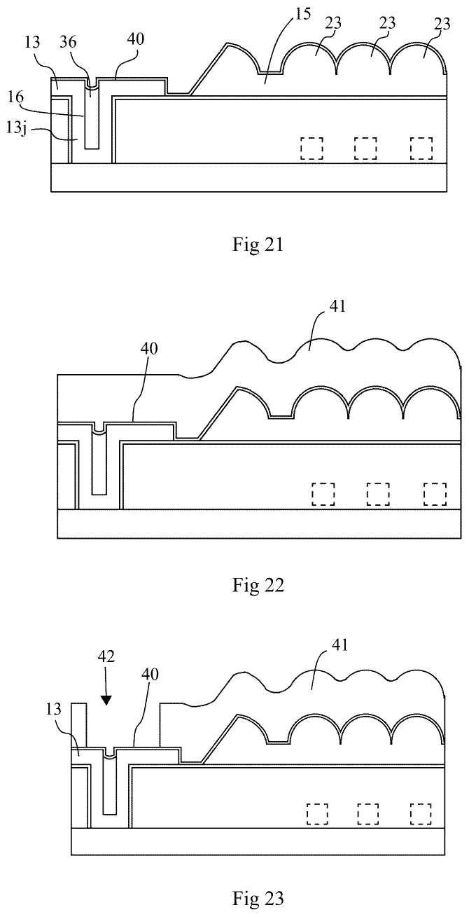

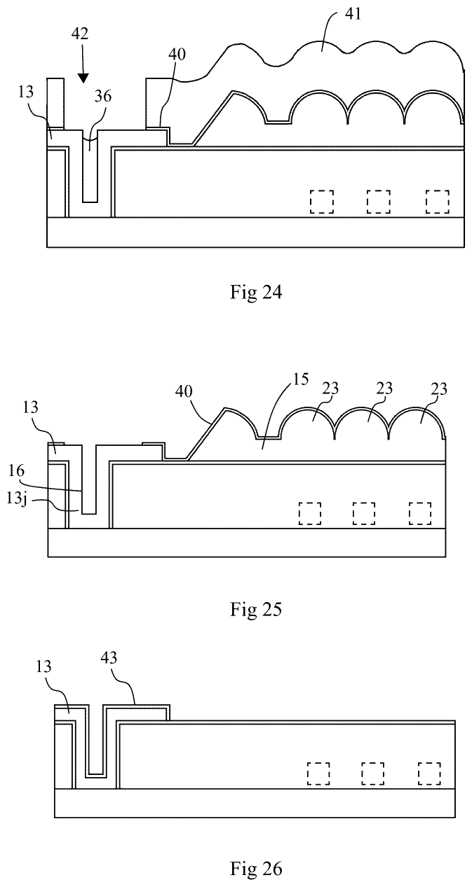

FIGS. 26 to 27 illustrate, schematically and partially, devices obtained at the end of successive steps of a method of manufacturing an image sensor according to another embodiment.

FIG. 26 is a drawing identical to FIG. 1, with the difference that contact pad 13 is covered with a dielectric or insulating layer 43. In this case, during the forming of protective layer 40 on contact pad 13, protective layer 40 may come into direct mechanical contact with dielectric layer 43 on contact area 13c, block 36 being interposed between dielectric layer 43 and the portion of protective layer 40 which covers block 36.

FIG. 27 is a drawing similar to FIG. 24 and illustrates a device obtained at the end of a step of removal of protective layer 40 and of dielectric layer 43 in each opening 42 opposite pads 13 to expose block 36.

FIG. 28 is a drawing similar to FIG. 25 and illustrates a device obtained at the end of a step of removal of resin layer 41 and of the blocks 36 present in the gaps 16 delimited by the junction portions 13j of contact pads 13. A portion of dielectric layer 43 is thus kept in gaps 16. Dielectric layer 43 advantageously enables to protect the contact pad 13 from corrosion during the subsequent steps of the manufacturing method.

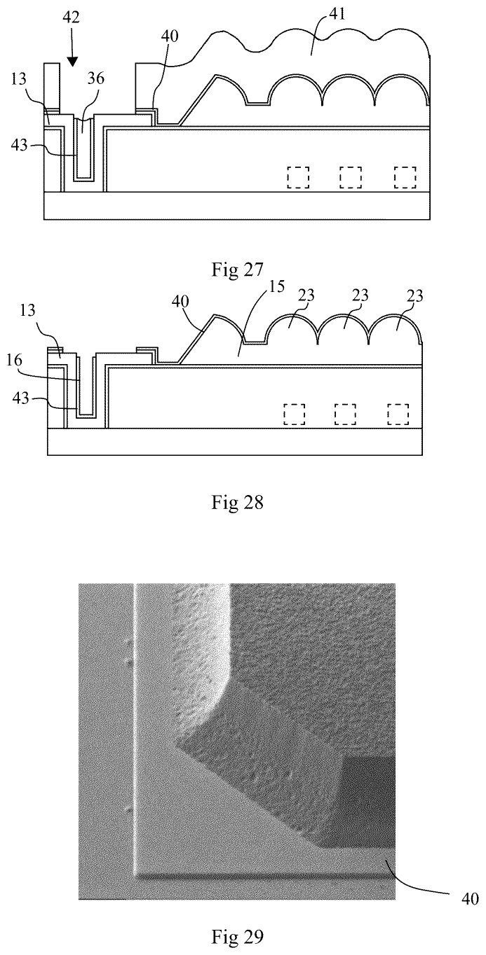

FIG. 29 is an image obtained by scanning electron microscopy of a device illustrated in FIG. 25, obtained at the end of a step of removal of protective layer 40 opposite pads 13. The kept portion of protective layer 40 covering layer 15 can be seen in FIG. 29.

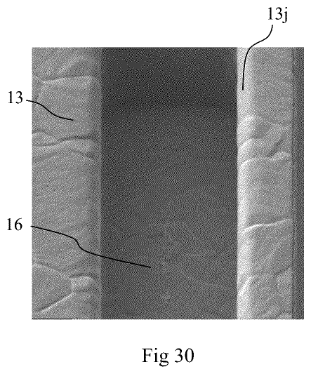

FIG. 30 is an image obtained by scanning electron microscopy of a device at the step illustrated in FIG. 25. As can be seen in this drawing, the junction portion 13j of contact pad 13 is fully exposed and the block 36 previously present in the gap 16 delimited by portion 13j of contact pad 13 has been fully removed.

An advantage of the methods described hereabove is that the remote plasma etching described in relation with FIG. 19 generates no polymer fibers, conversely to the physical etching of the step of FIG. 6. Layer 40 is thus deposited perfectly conformally on the surface of layer 15, which enables it to fulfil its role of protection of layer 15. A specific step of cleaning of the residual polymer fibers before the deposition of layer 40 may further be avoided, and layer 25 may be removed by means of a solvent-based wet etching solution.

Another advantage of the above-described embodiments is that the step of remote plasma etching is highly selective and enables not to consume the material of substrate 10.

Another advantage of the above-described embodiments is that the step of remote plasma etching of layer 15 causes the forming of a slope in this same layer 15 opposite pads 13, this slope being controllable so as to increase the conformality and the strength of the encapsulation layer 40 which covers it.

Various embodiments and variants have been described. Those skilled in the art will understand that certain features of these various embodiments and variants may be combined, and other variants will occur to those skilled in the art. In particular, the described embodiments are not limited to the above-mentioned examples of dimensions and of materials.

Finally, the practical implementation of the described embodiments and variants is within the abilities of those skilled in the art based on the functional indications given hereabove.

Method of manufacturing an image sensor comprising the following steps, in the order: a) the forming of an opening (11) in a semiconductor substrate (10) including a first surface (10s) and a second surface (10i) opposite to the first surface (10s), the opening (11) extending from the first surface (10s) to the second surface (10i), and the forming of at least one electrically-conductive pad (13) including a first portion (13c) extending over the first surface (10s) and a second portion (13j) covering the flanks of the opening (11) and delimiting a gap (16) in the opening (11); b) the forming of a plurality of microlenses (23) in a layer (15) made of a first resin, the layer (15) made of the first resin covering the electrically-conductive pad (13) and penetrating into the gap (16); c) the forming of a mask (25) made of a second resin on top of and in contact with the layer (15) made of the first resin; d) the chemical plasma etching of the layer (15) made of the first resin, through the mask (25) delimiting a block (36) of the first resin in the gap (16); e) the deposition of a protective layer (40) on the plurality of microlenses (23) and on the block (36); f) the removal of the portion of the protective layer (40) covering the block (36); and g) the etching of the block (36).

Method including at step a), the forming of a plurality of photodetectors (12) in the semiconductor substrate (10).

During step d), the contact pad (13) is exposed.

At step b), the forming of the microlenses (23) comprises a step h) of forming of structures (21) in the form of microlenses in a layer (19) made of a third resin, followed by a step i) of transfer of said structures (21) into the layer (15) made of the first resin by physical etching.

At step h), the structures (21) are formed by photolithography and flow.

After step d), the mask (25) is removed by means of a solvent.

The layer (15) made of the first resin is crosslinked.

The layer (15) made of the first resin is non-photosensitive.

The plasma used at steps d) and g) comprises oxygen.

The protective layer (40) is made of an oxide, for example of silicon oxynitride (SiON).

Image sensor comprising: a semiconductor substrate (10) inside and on top of which are integrated a plurality of photodetectors (12), the semiconductor substrate (10) including a first surface (10s) and a second surface (10i) opposite to the first surface (10s) and an opening (11) extending from the first surface (10s) to the second surface (10i); an electrically-conductive pad (13) including a first portion (13c) extending over the first surface (10s) and a second portion (13j) covering the flanks of the opening (11) and delimiting a gap (16) in the opening (11); a layer made of a first resin (15) covering the first surface (10s) in which a plurality of microlenses (23) are formed, said layer (15) made of the first resin including an opening facing the electrically-conductive pad (13), said opening having inclined side walls (35); and a protective layer (40) covering the layer (15) made of the first resin and which does not extend inside or on top of the gap (16).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of manufacturing an image sensor, the method comprising the following steps, in order:
a) forming of an opening in a semiconductor substrate comprising a first surface and a second surface opposite to the first surface, the opening extending from the first surface to the second surface, and the forming of at least one electrically-conductive pad comprising a first portion extending over the first surface and a second portion covering flanks of the opening and delimiting a gap in the opening;
b) forming a plurality of microlenses in a layer made of a first resin, the layer made of the first resin covering the electrically-conductive pad and penetrating into the gap;
c) forming a mask made of a second resin on top of and in contact with the layer made of the first resin;
d) chemical plasma etching of the layer made of the first resin, through the mask delimiting a block of the first resin in the gap;
e) depositing a protective layer on the plurality of microlenses and on the block;
f) removing a portion of the protective layer covering the block; and
g) chemical plasma etching the block.

2. The method according to claim 1, further comprising, at step a), forming a plurality of photodetectors in the semiconductor substrate.

3. The method according to claim 1, wherein during step d), the electrically-conductive pad is exposed.

4. The method according to claim 1, wherein, at step b), the forming of the plurality of microlenses includes a step h) of forming structures in a form of microlenses in a layer made of a third resin, followed by a step i) of transferring the structures into the layer made of the first resin by physical etching.

5. The method according to claim 4, wherein, at step h), the structures are formed by photolithography and flow.

6. The method according to claim 1, wherein, after step d), the mask is removed using a solvent.

7. The method according to claim 1, wherein the layer made of the first resin is crosslinked.

8. The method according to claim 1, wherein the layer made of the first resin is non-photosensitive.

9. The method according to claim 1, wherein the plasma used at steps d) and g) comprises oxygen.

10. The method according to claim 1, wherein the protective layer is made of an oxide.

11. The method according to claim 10, wherein the protective layer is made of silicon oxynitride (SiON).

12. An image sensor, comprising:
a semiconductor substrate, including:
a plurality of photodetectors in the semiconductor substrate;
a first surface and a second surface opposite to the first surface; and
a first opening extending from the first surface to the second surface;
an electrically-conductive pad comprising a first portion extending over the first surface and a second portion covering flanks of the first opening and delimiting a gap in the first opening;
a layer made of a first resin covering the first surface in which a plurality of microlenses are formed, the layer made of the first resin comprising a second opening facing the electrically-conductive pad, the second opening having inclined side walls; and
a protective layer covering the layer made of the first resin, the protective layer does not extend inside or on top of the gap.

13. The image sensor of claim 12, wherein the inclined side walls extend to the first surface of the semiconductor substrate.

14. The image sensor of claim 12, further comprising a first insulating layer on the first surface of the substrate, the first insulating layer being between the electrically-conductive pad and the substrate.

15. The image sensor of claim 14, further comprising a second insulating layer on regions of the electrically-conductive pad.

16. The image sensor of claim 15, wherein the second insulating layer is in the gap.

17. A method, comprising:
forming a conductive pad in a first through opening in a substrate, the substrate having a first surface opposite a second surface, the first through opening extending from the first surface to the second surface, the conductive pad being on the first surface and extending between sidewalls of the substrate, the conductive pad having sidewalls facing each other and delimiting a gap;
forming a first resin layer on the first surface of the substrate and forming a plurality of microlenses, a portion of the first resin layer being in the gap, the first resin layer being on the conductive pad, the plurality of microlenses being made of the first resin; and
removing the portion of the first resin layer in the gap and exposing a region of the conductive pad.

18. The method of claim 17, wherein removing the portion of the first resin layer forms slanted sidewalls of the first resin layer, the slanted sidewalls extending to the first surface of the substrate.

19. The method of claim 17, wherein removing the portion of the first resin layer includes:
forming a protective layer on the plurality of microlenses, the conductive pad, and over the gap, including the portion of the first resin layer in the gap;
forming a second resin layer on the protective layer; and
removing a portion of the second resin layer, the removed portion of the second resin layer being over the gap.

20. The method of claim 17, wherein removing is carried out via chemical plasma etching.
